(19) United States
(12) Patent Application Publication
(10) Pub. No.: US 2020/0393519 A1
(43) Pub. Date: Dec. 17, 2020

(54) INFORMATION PROVIDING DEVICE, INFORMATION PROVIDING METHOD, AND INFORMATION PROVIDING SYSTEM

(71) Applicant: HONDA MOTOR CO., LTD., Tokyo (JP)

(72) Inventors: Yoshihiro MATSUNAGA, Wako-shi (JP); Sho TAKADA, Wako-shi (JP); Mitsuhiro ITO, Wako-shi (JP); Nobuyuki SASAKI, Wako-shi (JP); Ryo OSHIMA, Wako-shi (JP); Mio OSHIMA, Wako-shi (JP)

(21) Appl. No.: 17/004,844

(22) Filed: Aug. 27, 2020

Related U.S. Application Data
(63) Continuation of application No. PCT/JP2018/044022, filed on Nov. 29, 2018.

(30) Foreign Application Priority Data
Mar. 20, 2018 (JP) 2018-053086

(51) Int. Cl. G01R 31/42; G06F 1/28; G01M 15/00

(52) U.S. Cl. CPC G01R 31/42; G01M 15/00; G06F 1/28

(57) ABSTRACT

An information providing device includes: a reception unit configured to receive operation information on a power supply device from the power supply device that supplies power to an electric apparatus detachably connected thereto; an evaluation unit configured to evaluate how the power supply device is used based on the received operation information; and a provision unit configured to provide a user of the power supply device with information based on an evaluation result of the evaluation unit.

### CROSS-REFERENCE TO RELATED APPLICATION(S)

This application is a Continuation of International Patent Application No. PCT/JP2018/044022, filed Nov. 29, 2018, which claims priority to and the benefit of Japanese Patent Application No. 2018-053086, filed on Mar. 20, 2018, the entire disclosures of which are incorporated herein by reference.

### BACKGROUND OF THE INVENTION

### Field of the Invention

The present invention relates to an information providing technique related to a power supply device.

### Description of the Related Art

Techniques for collecting and managing information on apparatuses using a communication network have been proposed. For example, Japanese Patent Laid-Open No. 2003-167653 discloses a system that collects information on a battery included in an electric apparatus via a communication network and examines the battery.

A power supply destination of the battery built in an electric apparatus is the electric apparatus, and a use aspect of the battery is limited. On the other hand, regarding power supply devices typified by generators and portable batteries, electric apparatuses to which electric power is supplied are various. For this reason, there are cases where users use the power supply devices inefficiently or unsuitably without noticing. For developers of power supply devices, examples of such use aspects are useful material for subsequent development.

### SUMMARY OF THE INVENTION

An object of the present invention is to provide a technique that allows a user to recognize whether how a power supply device is used is appropriate.

According to an aspect of the present invention, there is provided an information providing device comprising: a reception unit configured to receive operation information on a power supply device from the power supply device that supplies power to an electric apparatus detachably connected thereto; an evaluation unit configured to evaluate how the power supply device is used based on the received operation information; and a provision unit configured to provide a user of the power supply device with information based on an evaluation result of the evaluation unit.

Further features of the present invention will become apparent from the following description of exemplary embodiments (with reference to the attached drawings).

### BRIEF DESCRIPTION OF THE DRAWINGS

FIG. 1 is a schematic diagram of an information providing system.

FIG. 2 is a block diagram of a power supply device according to one embodiment of the present invention.

FIG. 3 is a block diagram of an information providing device according to one embodiment of the present invention.

FIG. 4A is a flowchart showing a process example of the system of FIG. 1.

FIG, 4B is a flowchart showing a process example of the system of FIG. 1.

FIG. 5 is a flowchart showing a process example of the system of FIG. 1.

FIG. 6A is a diagram showing a display example of evaluation information.

FIG. 6B is a diagram showing a display example of the evaluation information.

FIG. 6C is a diagram showing a display example of the evaluation information.

FIG. 7 is a flowchart showing another process example of the information providing device of FIG. 3.

FIG. 8 is a block diagram of another power supply device.

FIG. 9 is a block diagram of another power supply device.

### DESCRIPTION OF THE EMBODIMENTS

Hereinafter, embodiments will be described in detail with reference to the attached drawings. Note that the following embodiments are not intended to limit the scope of the claimed invention, and limitation is not made an invention that requires all combinations of features described in the embodiments. Two or more of the multiple features described in the embodiments may be combined as appropriate. Furthermore, the same reference numerals are given to the same or similar configurations, and redundant description thereof is omitted.

### System Configuration

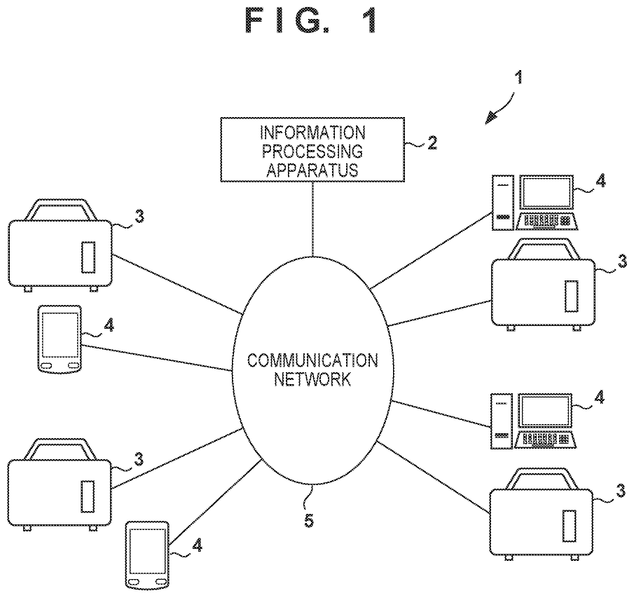

FIG. 1 is a schematic diagram of an information providing system 1. The information providing system 1 includes an information providing device 2, a plurality of power supply devices 3, and a plurality of terminals 4 that are communicatively connected via a communication network 5. Although four power supply devices 3 are illustrated in the shown example, a large number of power supply devices 3 can be included in the system 1.

The information providing device 2 is a computer that functions as an information providing server in the information providing system 1. Each of the power supply devices 3 is a device that supplies power to an electric apparatus, and is assumed to be a transportable power supply device in the case of this embodiment, but may be a stationary power supply device. The transportable power supply device would be able to be transported to a place of use according to a user's use such as leisure, business, or emergency. The power supply device 3 may be an object owned or rented by the user.

Each of the terminals 4 is a computer used by the user of the power supply device 3, and is, for example, a PC or a mobile terminal. The terminal 4 includes a display device and a communication device. In the case of the embodiment, information provided to the user of the power supply device 3 is transmitted from the information providing device 2 to the terminal 4. However, it can be also transmitted to the power supply device 3 depending on a function of the power supply device 3. Alternatively, the user may be able to select either the terminal 4 or the power supply device 3 as a transmission destination of the information.

In the information providing system 1, the information providing device 2 collects operation information on an operation aspect from the power supply device 3 via the communication network 5 such as the Internet, evaluates how the power supply device 3 is used from the collected information, and provides the terminal 4 with information based on an evaluation result. The user of the power supply device 3 can understand whether how they use is appropriate for the device from the provided information, and obtain useful information as reference material for future use of the device or purchase of another device.

The information providing device 2 can be operated by, for example, a developer or a rental company of the power supply device 3. Since these companies can obtain information related to an actual state of the working aspect of the power supply device 3, they can use it as future development materials and sales materials.

### Power Supply Device

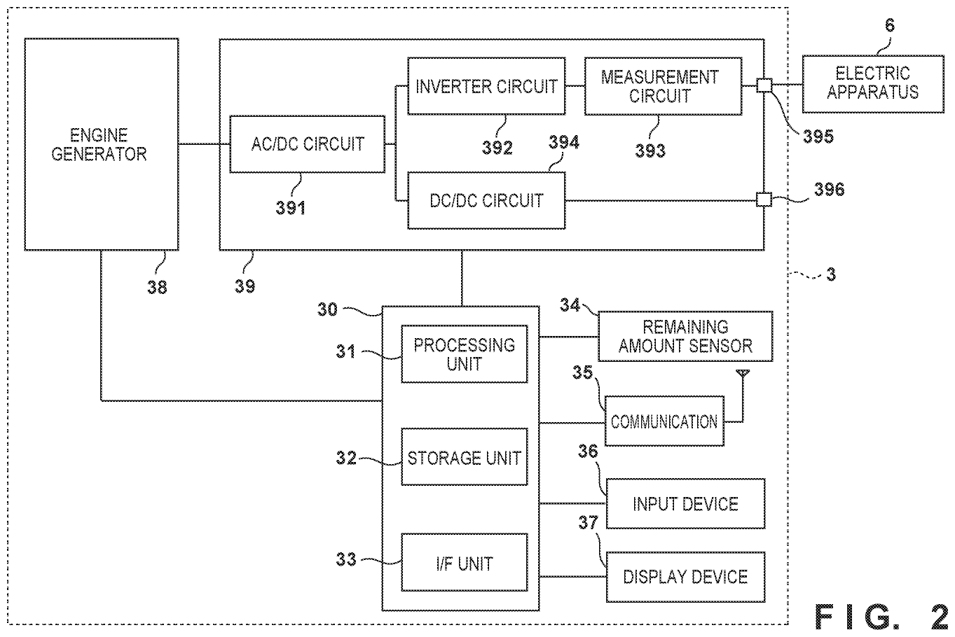

FIG. 2 is a block diagram of the power supply device 3. The power supply device 3 of the embodiment is a generator-type power supply device including an engine generator 38. The engine generator 38 of the embodiment generates AC power driven by fuel. The fuel is, for example, gasoline, liquefied petroleum gas, or hydrogen.

A power supply circuit 39 is a circuit that converts voltage generated by the engine generator 38 into predetermined AC and DC. An AC/DC circuit 391 includes a rectifying/smoothing circuit or the like that rectifies and smooths AC generated by the engine generator 38. An inverter circuit 392 is a circuit that converts DC output from the AC/DC circuit 391 into stable AC having a predetermined frequency.

A measurement circuit 393 includes a current sensor and a voltage sensor, measures AC voltage and AC current supplied from the inverter circuit 392 to an electric apparatus 6 connected to an AC outlet 395, and outputs measurement results to a control circuit 30. The electric apparatus 6 that can be driven by AC power is detachably connected to the AC outlet 395. As the electric apparatus 6, when the power supply device 3 is used for leisure, an electric load such as a cooker, an air conditioner, a television, a lighting fixture, or a dryer can be mentioned. As the cooker, a hot plate, a kettle, a microwave oven, a grill, a mixer, or the like can be mentioned. When the power supply device 3 is used for business, an electric load such as a power tool, a large lighting device, or a compressor can be mentioned.

A DC/DC circuit 394 converts a level of DC voltage output from the AC/DC circuit 391, supplies an operation voltage to the control circuit 30 or the like, and outputs from a DC outlet 396. The electric apparatus 6 that can be driven by DC power is detachably connected to the DC outlet 396.

The control circuit 30 is a circuit that controls the power supply device 3. The control circuit 30 includes a processing unit 31, a storage unit 32, and an I/F (interface) unit 33. The processing unit 31 is a processor typified by a CPU, and executes a program stored in the storage unit 32. The storage unit 32 is a storage device such as a RAM, a ROM, or a hard disk. The storage unit 32 stores various types of data in addition to the program executed by the processing unit 31. The I/F unit 33 relays transmission and reception of signals between an external device and the processing unit 31.

A remaining amount sensor 34 detects a remaining amount of fuel in the engine generator 38. The remaining amount sensor 34 can be provided in a fuel tank that stores fuel. Fuel consumption of the engine generator 38 can be calculated from a fuel consumption amount detected by the remaining amount sensor 34 and a power consumption amount of the electric apparatus 6 measured by the measurement circuit 393.

A communication device 35 is a wireless communication device that performs information communication with the information providing device 2 via the communication network 5. The communication device 35 may be a wired communication device. An input device 36 is a device that receives an operation input of the user of the power supply device 3, and is, for example, a plurality of switches. A display device 37 is a device that displays information to the user of the power supply device 3, and is, for example, an image display device, such as a liquid crystal display device, or a light-emitting element, such as an LED.

The processing unit 31 transmits the detection result of the remaining amount sensor 34 and the measurement results of the measurement circuit 393 to the information providing device 2 by the communication device 35 as the operation information on the power supply device 3. The actual detection result and measurement results can be used for later-described evaluation, and evaluation accuracy can be improved. The measurement results of the measurement circuit 393 can be used as information related to a type of the electric apparatus 6 connected to the AC outlet 395 of the power supply device 3, and in particular, can be used for estimating the type. The power supplied to the electric apparatus 6 shows a waveform characterized by the type of the electric apparatus 6. The type of the connected electric apparatus 6 can be estimated from its feature quantity.

The feature quantity is, for example, apparent power and power factor. The power factor is found by dividing effective power by the apparent power, or is found as a cosine (cos θ) of a phase difference between voltage and current. In the latter case, the measurement circuit 393 measures the phase difference θ. Furthermore, the feature quantity may include a time from start of the electric apparatus 6 to stable operation, or a peak value of start current flowing through the electric apparatus 6 when the electric apparatus 6 starts. By converting a relationship between the type of the electric apparatus 6 and the feature quantity into data in advance as a feature quantity map and comparing the feature quantity map with a feature quantity measured with the measurement circuit 393, the type of the electric apparatus 6 can be estimated. The type of the electric apparatus 6 can be also estimated by applying a known apparatus separation technique.

### Information Providing Device

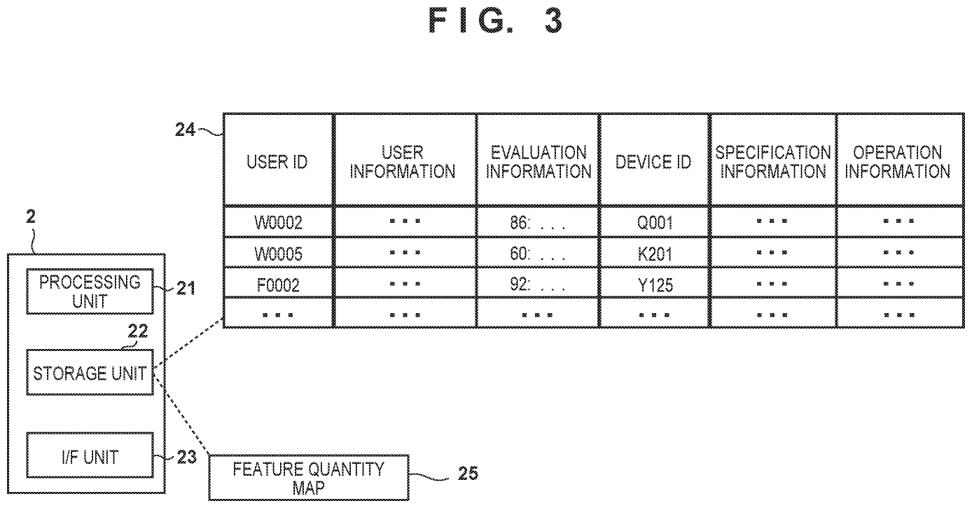

FIG. 3 is a block diagram of the information providing device 2. The information providing device 2 includes a processing unit 21, a storage unit 22, and an I/F (interface) unit 23. The processing unit 21 is a processor typified by a CPU, and executes a program stored in the storage unit 22. The I/F unit 23 relays transmission and reception of signals between an external device and the processing unit 21. The I/F unit 23 includes a wired or wireless communication interface capable of communicating with the power supply devices 3 and the terminals 4 via the communication network 5. The storage unit 22 is a storage device such as a RAM, a ROM, or a hard disk.

The storage unit 22 stores various types of data in addition to the program executed by the processing unit 21. In the example of FIG. 3, databases 24 and 25 are illustrated as data stored in the storage unit 22. The database 24 is a database that has accumulated data on the power supply devices 3 and their users. “User ID” is an identifier assigned in advance to identify the user of the power supply device 3. “User information” is information on the user, and can include information, such as a name, an address, or an email address. “Evaluation information” is an evaluation point and advice regarding how to use the power supply device 3.

“Device ID” is an identifier assigned in advance to identify the individual power supply device 3. “Specification information” is information related to specification of the power supply device 3. The specification information includes, for example, a model, rated output, a type of operation mode, a continuous operation available time, or presence/absence of an inverter. “Operation information” accumulates the operation information received from power supply device 3 or a link to a storage area of the operation information in the storage unit 22.

The database 25 is a database that has accumulated a feature quantity map. The processing unit 21 collates the measurement results of the measurement circuit 393 included in the operation information transmitted from the power supply device 3 with the feature quantity map, and thereby estimates the electric apparatus 6 currently connected to the power supply device 3.

The operation information transmitted from the power supply device 3 may be the measurement results of the measurement circuit 393 themselves, or may be the feature quantity, power consumption, startup power, or the like of power supplied to the electric apparatus 6 calculated on the power supply device 3 side. In the embodiment, the information providing device 2 side estimates the type of the electric apparatus 6, but the power supply device 3 side may estimate it and include an estimation result in the operation information to transmit to the information providing device 2.

Regarding the evaluation information and the operation information, only the latest information may be accumulated, or information in a past certain period on a daily basis or the like may be accumulated.

### Process Example

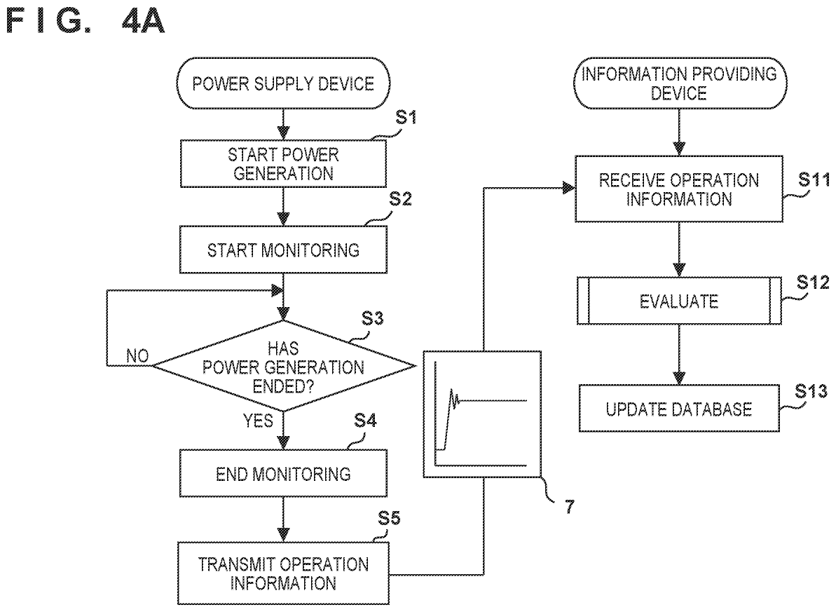

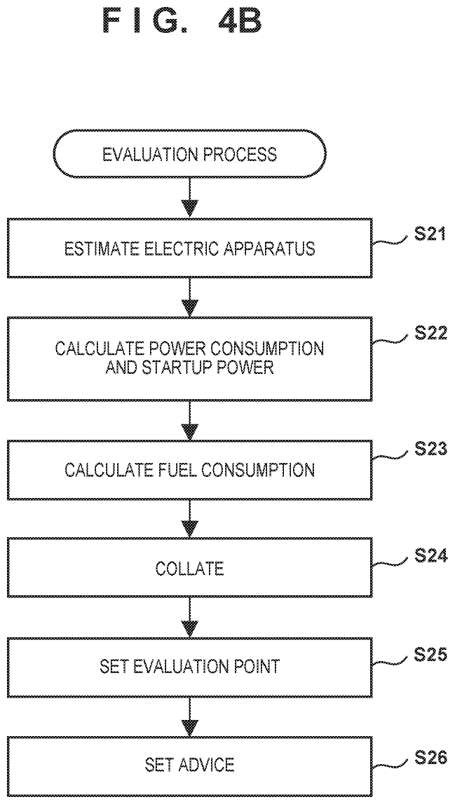

A process example of the information providing system 1 will be described. FIG. 4A shows a process example between the information providing device 2 and the power supply device 3, and shows a process example in which the information providing device 2 collects the operation information on the power supply device 3. In the information providing device 2, the processing unit 21 performs the process, and in the power supply device 3, the processing unit 31 performs the process.

In S1, power generation of the engine generator 38 in the power supply device 3 is started. The engine generator 38 starts by, for example, the user's start. operation. In S2, monitoring of the remaining amount sensor 34 and the measurement circuit 393 is started. When the monitoring is started, for example, the detection result of the remaining amount sensor 34 and the measurement results of the measurement circuit 393 are accumulated in the storage unit 32 together with time at a predetermined sampling cycle.

In S3, it is determined whether the power generation of the engine generator 38 has ended. When it has ended, the process proceeds to S4 to end monitoring. In S5, operation information 7 including the detection result of the remaining amount sensor 34 and the measurement results of the measurement circuit 393 accumulated in the storage unit 32 during the monitoring and the device ID of the power supply device 3 is transmitted to the information providing device 2. The operation information 7 is information indicating a use history of the power supply device 3 in the case of this example, For the purpose of reducing a communication amount, part of the detection result of the remaining amount sensor 34 and the measurement results of the measurement circuit 393 may be included in the operation information 7. For example, sampling may be increased during a period when supplied power fluctuation is large as seen at the time of connection or separation of the electric apparatus 6, whereas sampling may be reduced by thinning out data during a period when power supply to the electric apparatus 6 is stable.

In the case of the embodiment, the detection result of the remaining amount sensor 34 and the measurement results of the measurement circuit 393 are logged during use, and the operation information 7 is transmitted after the power generation ends, but the operation information including the detection result of the remaining amount sensor 34 and the measurement results of the measurement circuit 393 may be transmitted to the information providing device 2 in real time.

The information providing device 2 receives the operation information in S11. In S12, the information providing device 2 evaluates how the power supply device 3 is used based on the received operation information. A detailed example will be described later. In S13, the database 24 is updated.

FIG. 4B is a flowchart showing an example of an evaluation process of S12, In S21, the feature quantity is calculated from the measurement results of the measurement circuit 393, and the calculated feature quantity is collated with the feature quantity map in the database 25 to estimate the type of the electric apparatus 6 connected to the power supply device 3, a connection time zone, a frequency of connection and separation, or the like.

In S22, for each electric apparatus 6 estimated in S21, its power consumption and startup power are calculated from the measurement results of the measurement circuit 393. In S23, for each electric apparatus 6 estimated in S21, fuel consumption of the engine generator 38 is calculated from the measurement results of the measurement circuit 393 and the detection result of the remaining amount sensor 34. In S24, the “specification information” on the power supply device 3 accumulated in the database 24 is referred to and collated with estimation results and calculation results in S21-S23.

In S25, the evaluation point indicating whether ow the power supply device 3 is used is appropriate or efficient for the device is set from a collation result in S24. For example, the evaluation point may be calculated by subtracting points corresponding to the collation result in S24 from a maximum of 100 points. For example, if the electric apparatus 6 estimated in S21 is not suitable for use in the power supply device 3, which can be targeted for deduction of points. If the power consumption or the startup power calculated in S22 is not suitable for the power supply device 3 in terms of the rated output, which can be targeted for deduction of points. Both of the power consumption and the startup power may be targeted for evaluation, or either one may be targeted for evaluation. If the fuel consumption calculated in S23 can be improved by switching the operation mode of the power supply device 3 (for example, switching from a high rotation mode to a low rotation mode of an engine), which can be targeted for deduction of points. In this way, the evaluation point can be set.

In S26, advice to the user regarding how to use the power supply device 3 is set based on the collation result in S24. Multiple types of advice can be prepared and stored in the storage unit 22. Advice is basically something that prompts the user to improve their usage. For example, if the electric apparatus 6 estimated in S21 is not suitable for use in the power supply device 3, advice indicating a suitable type of electric apparatus 6 and an unsuitable type of electric apparatus 6 can be selected. If the power consumption or the startup power calculated in S22 is not suitable for the power supply device 3 in terms of the rated output, advice that introduces another suitable power supply device can be selected. If the fuel consumption calculated in S23 can be improved by switching the operation mode of the power supply device 3, advice indicating a desirable operation mode can be selected. The evaluation point in S25 and the advice in S26 are accumulated in the database 24 as the evaluation information.

Next, FIG. 5 shows a process example between the information providing device 2 and the terminal 4, and shows a process example in which the information providing device 2 provides the terminal 4 with information. In the information providing device 2, the processing unit 21 performs the process, and in the terminal 4, its processing unit (CPU or the like) performs the process.

The terminal 4 transmits an evaluation request together with its user ID to the information providing device 2 in S31. The information providing device 2 receives the request in S41, and generates evaluation information in S42. The evaluation information is generated by referring to the database 24 and obtaining information accumulated in the evaluation information. In subsequent S43, the information providing device 2 transmits the evaluation information generated in S42 to the terminal 4 that made the request. The terminal 4 receives the evaluation information in S32, and displays the received evaluation information on the display device in S43. The user of the power supply device 3 can recognize whether how the power supply device 3 is used is appropriate based on the displayed evaluation information.

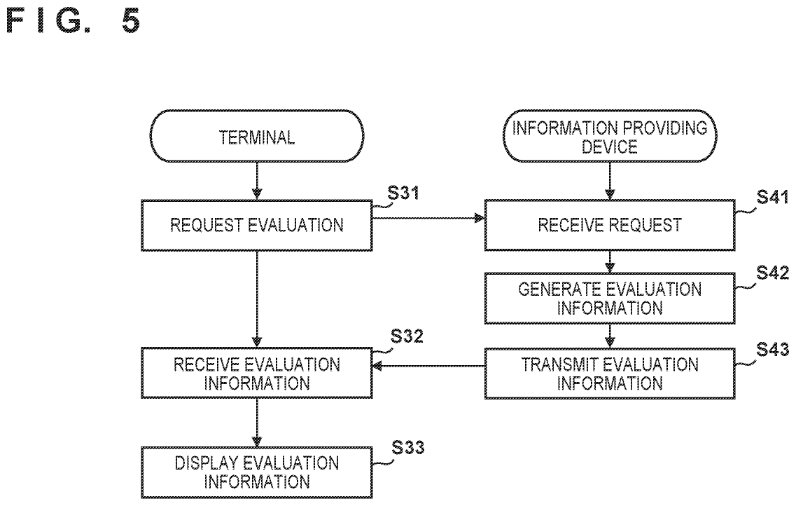

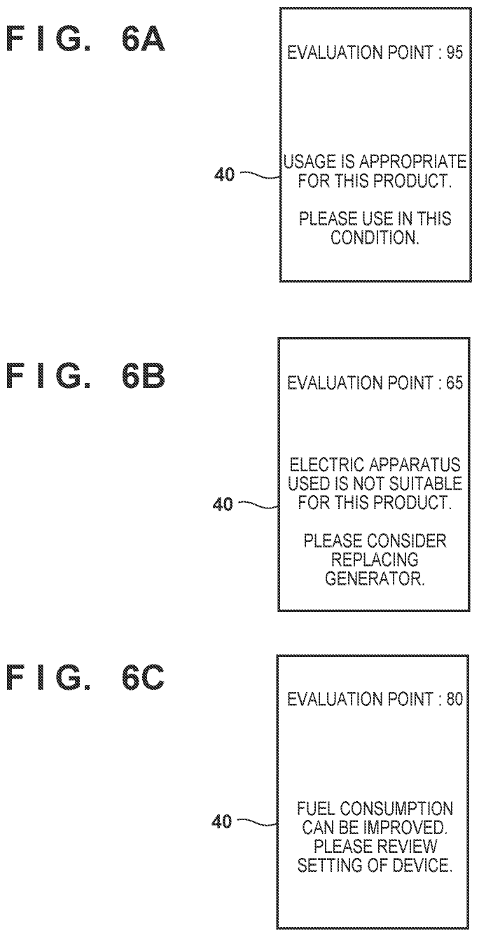

FIGS. 6A-6C are examples of the evaluation information and illustrate display examples 40 displayed on the display device of the terminal 4 in S33. The display examples 40 include evaluation points and advice. The user can sensuously recognize whether how the power supply device 3 is used is correct based on the evaluation point, and can specifically recognize an improvement point of how to use based on the advice.

The example of FIG. 6A shows that the evaluation point is high and contents of the advice also indicate the device is generally used appropriately. The example of FIG. 6B shows that the evaluation point is low and contents of the advice request improvement of how to use. Specifically, they point out that the type of the electric apparatus 6 estimated in S21 is not suitable for use in the power supply device 3. The user will reconsider the used electric apparatus 6 or consider replacing the power supply device 3 if the user wants to use the electric apparatus 6. The example of FIG. 6C shows that the evaluation point is acceptable but contents of the advice propose to improve how to use. Specifically, there is room for improvement in fuel consumption calculated in S23, and it is proposed to change setting of the power supply device 3 such as changing the operation mode. The user will review the setting of the power supply device 3.

As described above, according to the embodiment, because the evaluation information is provided, the user of the power supply device 3 can understand whether how they use is appropriate for the device, and obtain useful information as reference material for future device use or purchasing another device. The operator of the information providing device 2 can obtain data on the use aspect of the power supply device 3 as the operation information so they can utilize it for future developing material or the like of the power supply device 3.

### Other Embodiments

### Other Information Providing Process Example

Although in the embodiment described above, the information providing device 2 generates the evaluation information triggered by the request from the terminal 4 and transmits it to the terminal 4, methods are not limited to this. For example, after setting the advice in S26 of FIG. 4B, the evaluation information may be generated and transmitted to the terminal 4 or the power supply device 3.

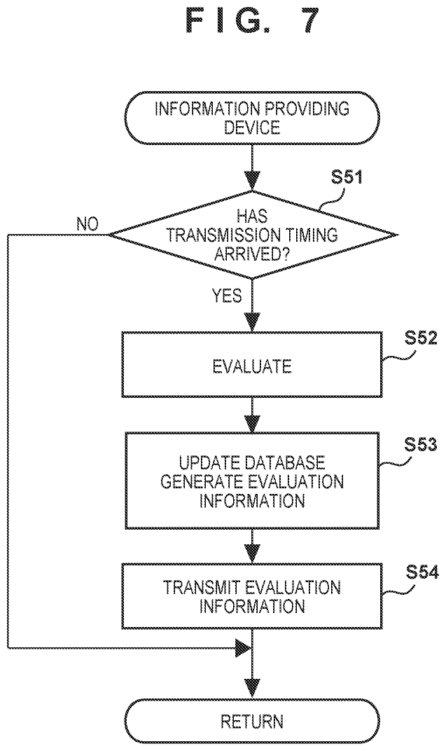

As another method, for example, the information providing device 2 may perform the evaluation process of S12 at a predetermined timing to generate evaluation information, and transmit it to the terminal 4. The timing can be designated in advance by the user by, for example, day, hour, and cycle, and this condition can be stored in the “user information” of the database 24. The information providing device 2 refers to the “user information” of the database 24, generates evaluation information when the designated timing comes, and sends the evaluation information to the terminal 4 by email or the like. In the case of email, a transmission destination address can be stored in the “user information” of the database 24. FIG. 7 is a flowchart showing one example thereof, and the processing unit 21 of the information providing device 2 performs it.

In S51, the “user information” of the database 24 is referred to and it is determined whether transmission timing has arrived. When the transmission timing has arrived, the process proceeds to S52, and when the transmission timing has not arrived, the process ends. In S52, the evaluation process is performed. The contents are the same as those of the evaluation process of S12. In S53, the evaluation information of the database 24 is updated and the evaluation information to be provided to the user is generated. In S54, the evaluation information generated in S53 is transmitted to the user's terminal 4. This ends the processes.

### Other Configuration Example of Power Supply Device

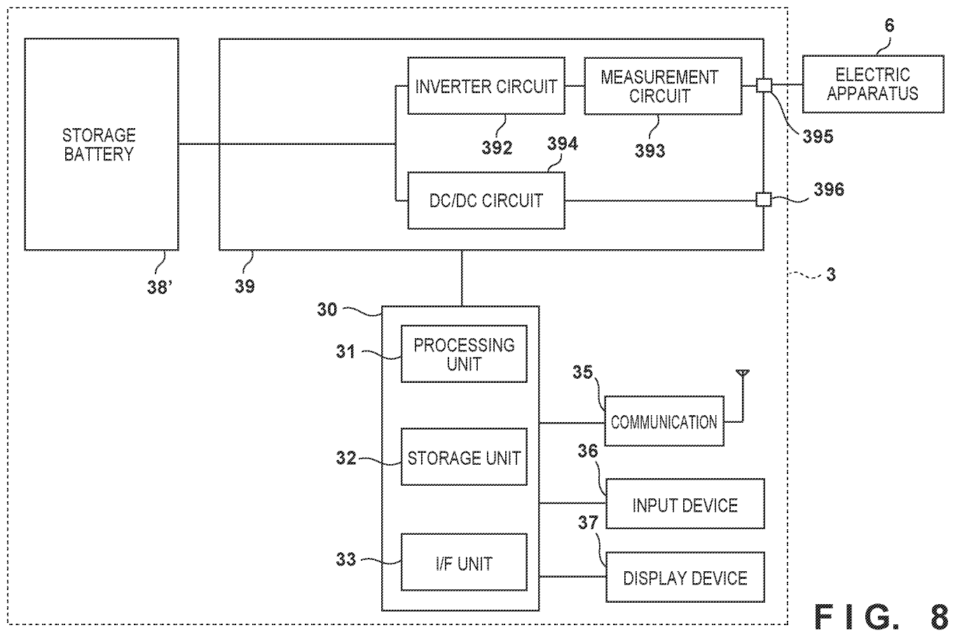

The power supply device 3 illustrated in FIG. 2 includes the engine generator 38, but the configuration is not limited to this. FIG. 8 shows a power supply device 3 employing a storage battery 38′ instead of the engine generator 38. Description of parts common to the example of FIG. 2 will be omitted. The storage battery 38′ is, for example, a secondary battery such as a lithium-ion battery, and outputs a DC voltage such as 48 V to an inverter circuit 392 or a DC/DC circuit 394. The evaluation contents of the power supply device 3 in the example of FIG. 8 can include evaluation contents related to the life of the storage battery 38′ in addition to the evaluation contents specific to the engine generator 38 among the evaluation contents described above. Therefore, the operation information can include charging/discharging information on the storage battery 38′. The charging/discharging information may be the measurement results of the measurement circuit 393. Evaluation contents based on the charging/discharging information can include, for example, a charge/discharge frequency of the storage battery 38′, presence/absence of overcharge or overdischarge, a remaining amount at the start of charging, or a remaining amount at the end of charging. If there is any unfavorable usage in terms of the life of the storage battery 38′, its improvement can be advised.

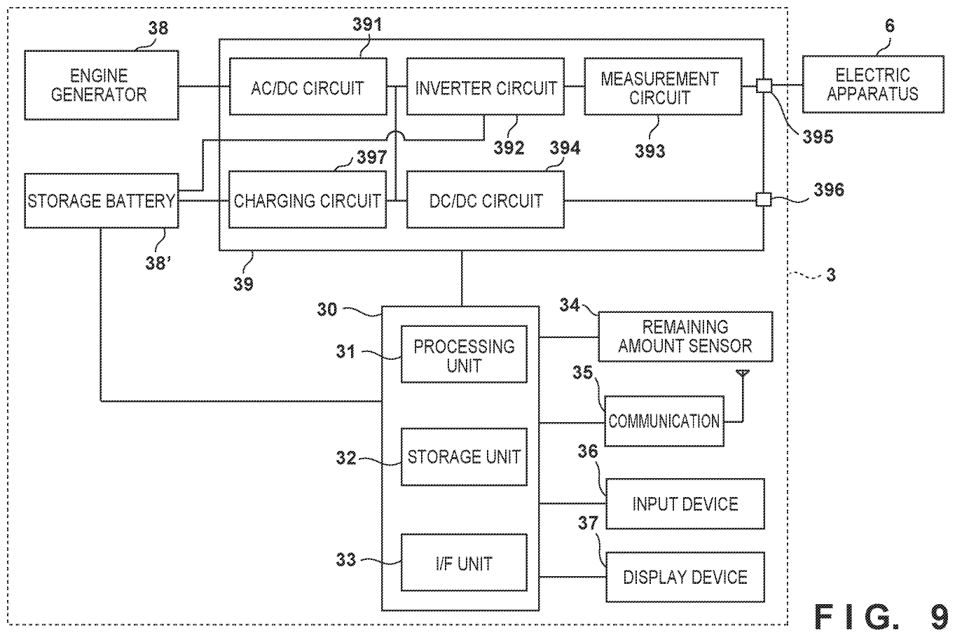

FIG. 9 shows a power supply device 3 including both the engine generator 38 and the storage battery 38′. Description of parts common to the example of FIG. 2 or 8 will be omitted. The inverter circuit 392 converts DC generated by an AC/DC circuit 391 or DC supplied from the storage battery 38′ into AC. A charging circuit 397 charges the storage battery 38′ based on power generated by the engine generator 38. The power supply device 3 shown in FIG. 9 can supply power stored in the storage battery 38′ to an electric apparatus 6 even after fuel of the engine generator 38 runs out.

### Summary of Embodiments

1. An information providing device (for example, 2) of the embodiment comprises:

a reception unit (for example, 21, 23, and S11) configured to receive operation information on a power supply device (for example, 3) from the power supply device that supplies power to an electric apparatus (for example, 6) detachably connected thereto;

an evaluation unit (for example, 21 and S12) configured to evaluate how the power supply device is used based on the received operation information; and

a provision unit (for example, 21, 23, S43, and S54) configured to provide a user of the power supply device with information based on an evaluation result of the evaluation unit.

According to this embodiment, it is possible to provide a technique that allows the user to recognize whether how they use the power supply device is appropriate.

2. In the embodiment,

the operation information includes measurement information indicating a measurement result of voltage and/or a measurement result of current that the power supply device is supplying to the electric apparatus, and

the evaluation unit evaluates how the power supply device is used based on the measurement information (for example, S21-S23).

According to the embodiment, how the power supply device is used can be evaluated. from voltage or current actually supplied to the electric apparatus, and evaluation accuracy can be improved.

3. In the embodiment,

the operation information includes measurement information indicating a measurement result of voltage and/or a measurement result of current that the power supply device is supplying to the electric apparatus, and

the evaluation unit estimates a type of the electric apparatus based on the measurement information (for example, S21), and evaluates how the power supply device is used based on the estimated type of the electric apparatus and specification of the power supply device.

According to the embodiment, it is possible to evaluate whether the type of the electric apparatus is suitable for the power supply device and prompt the user to connect an appropriate type of electric apparatus.

4. In the embodiment,

the operation information includes measurement information indicating measurement results of voltage and current that the power supply device is supplying to the electric apparatus, and

the evaluation unit evaluates how the power supply device is used based on power consumption and/or startup power of the electric apparatus based on the measurement information, and specification of the power supply device for example, S22)

According to the embodiment, it is possible to evaluate whether rated output of the power supply device is suitable for the connected electric apparatus, and prompt the user to use an appropriate type of the power supply device.

5. In the embodiment,

when the power supply device includes an engine generator (for example, 38), the operation information includes:

fuel consumption information indicating a fuel consumption amount of the engine generator; and

measurement information indicating measurement results of voltage and current that the power supply device is supplying to the electric apparatus, and

the evaluation unit evaluates how the power supply device is used based on the fuel consumption information and the measurement information (for example, S23).

According to the embodiment, it is possible to prompt the user to select an operation mode of the power supply device that is advantageous in fuel consumption.

6. In the embodiment,

when the power supply device includes a storage battery (for example, 38′) that stores power supplied to the electric apparatus, the operation information includes charging/discharging information indicating a change in a power storage amount of the storage battery, and

the evaluation unit evaluates how the power supply device is used based on the charging/discharging information.

According to the embodiment, it is possible to prompt the user into how to use the power supply device advantageous in the life of the storage battery.

7. An information providing method of the embodiment comprises:

a reception step (for example, S11) of receiving, by a server (for example, 2), operation information on a power supply device (for example, 3) from the power supply device that supplies power to an electric apparatus (for example, 6) detachably connected thereto;

an evaluation step (for example, S12) of evaluating, by the server, how the power supply device is used based on the received operation information; and

a provision step (for example, S43 and S54) of providing, by the server, a user of the power supply device with information based on an evaluation result.

According to this embodiment, it is possible to provide a technique that allows the user to recognize whether how they use the power supply device is appropriate.

8. An information providing system (for example, 1) of the embodiment is

an information providing system comprising a. plurality of power supply devices (for example, 3) that supply power to electric apparatuses (for example, 6) detachably connected thereto, and an information providing device (for example, 2) capable of communicating with the power supply devices via a network (for example, 5),

wherein the information providing device includes:

a reception unit (for example, 21, 23, and S11) configured to receive operation information on the power supply devices from the power supply devices:

an evaluation unit (for example, 21 and S12) configured to evaluate how each of the power supply devices is used based on the received operation information; and

a provision unit (for example, 21, 23, S43, and S54) configured to provide users of the respective power supply devices with information based on an evaluation result of the evaluation unit.

According to this embodiment, it is possible to provide a technique that allows the users to recognize whether how they use the power supply devices is appropriate.

What is claimed is:

1. An information providing device comprising:
a reception unit configured to receive operation information on a power supply device from the power supply device that supplies power to an electric apparatus detachably connected thereto;
an evaluation unit configured to evaluate how the power supply device is used based on the received operation information; and
a provision unit configured to provide a user of the power supply device with information based on an evaluation result of the evaluation unit.

2. The information providing device according to claim 1,
wherein the operation information includes measurement information indicating a measurement result of voltage and/or a measurement result of current that the power supply device is supplying to the electric apparatus, and
wherein the evaluation unit evaluates how the power supply device is used based on the measurement information.

3. The information providing device according to claim 1,
the operation information includes measurement information indicating a measurement result of voltage and/or a measurement result of current that the power supply device is supplying to the electric apparatus, and
wherein the evaluation unit estimates a type of the electric apparatus based on the measurement information, and evaluates how the power supply device is used based on the estimated type of the electric apparatus and specification of the power supply device.

4. The information providing device according to claim 1,
wherein the operation information includes measurement information indicating measurement results of voltage and current that the power supply device is supplying to the electric apparatus, and
wherein the evaluation unit evaluates how the power supply device is used based on power consumption and/or startup power of the electric apparatus based on the measurement information, and specification of the power supply device.

5. The information providing device according to claim 1,
wherein when the power supply device includes an engine generator, the operation information includes:
fuel consumption information indicating a fuel consumption amount of the engine generator; and
measurement information indicating measurement results of voltage and current that the power supply device is supplying to the electric apparatus, and
wherein the evaluation unit evaluates how the power supply device is used based on the fuel consumption information and the measurement information.

6. The information providing device according to claim 1,
wherein when the power supply device includes a storage battery that stores power supplied to the electric apparatus, the operation information includes charging/discharging information indicating a change in a power storage amount of the storage battery, and
wherein the evaluation unit evaluates how the power supply device is used based on the charging/discharging information.

7. An information providing method comprising:
a reception step of receiving, by a server, operation information on a power supply device from the power supply device that supplies power to an electric apparatus detachably connected thereto;
an evaluation step of evaluating, by the server, how the power supply device is used based on the received operation information; and
a provision step of providing, by the server, a user of the power supply device with information based on an evaluation result.

8. An information providing system comprising a plurality of power supply devices that supply power to electric apparatuses detachably connected thereto, and an information providing device capable of communicating with the power supply devices via a network,
wherein the information providing device includes:
a reception unit configured to receive operation information on the power supply devices from the power supply devices;
an evaluation unit configured to evaluate how each of the power supply devices is used based on the received operation information; and
a provision unit configured to provide users of the respective power supply devices with information based on an evaluation result of the evaluation unit.
